(19) United States
(12) Patent Application Publication
(10) Pub. No.: US 2009/0121259 A1
(43) Pub. Date: May 14, 2009

(54) PAIRED MAGNETIC TUNNEL JUNCTION TO A SEMICONDUCTOR FIELD-EFFECT TRANSISTOR

(76) Inventors: Icko E. T. Iben, Santa Clare, CA (US); Alvin W. Strong, Essex Junction, VT (US)

Correspondence Address: HOFFMAN WARNICK LLC, 75 STATE ST, 14TH FLOOR, ALBANY, NY, 12207, US

(21) Appl. No.: 11/938,946

(22) Filed: Nov. 13, 2007

(51) Int. Cl. H01L 27/20

(52) U.S. Cl. 257/252; 257/E27.006

(57) ABSTRACT

A magnetic tunnel junction paired to a semiconductor field-effect transistor is described. In one embodiment, there is a circuit that comprises at least one semiconductor field-effect transistor and a magnetic tunnel junction coupled to the at least one semiconductor field-effect transistor. The magnetic tunnel junction has a control line that is configured to control operational characteristics of the at least one semiconductor field-effect transistor.

### BACKGROUND

This disclosure relates generally to semiconductor field effect transistors, and more specifically to maintaining performance of a semiconductor field effect transistor (FET) and/or FET circuit by coupling a magnetic tunnel junction (MTJ) to the FET.

Over time, performance of a typical FET device will degrade due to the effects of aging. Degradation in the performance of a FET device will impact the threshold voltage of the device and therefore the drive current. Currently, there are no approaches available that enable one to modulate the performance of the FET device during its operation without significantly separating the circuit from its normal operation, regardless of whether the FET is experiencing performance degradation. Current approaches all require that the FET device and/or circuit be separated and the action be instituted by external means, e.g., an anneal. In principle, if some of the electrical adjustable resistors known in the art were to be used, they would require a current source to apply the appropriate energy to the resistor through the device/circuit in question. Hence, the electrical separation of the device/circuit becomes difficult, requiring isolation devices or ‘switches’ that isolate both ends of the resistor and connect it to the current source.

In order to account for instances where it is desirable to modulate performance or negate degradation without relying on external means, a typical FET device can be designed to cover a wide range of performance points that one can envision the FET experiencing. Accounting for such a wide variation in performance points results in a compromise to the overall performance of the FET circuit because it is unknown what the performance of the device will really be due to process variations and/or age effects (e.g., hot carrier injection or negative bias instability) that can affect the device.

### SUMMARY

In one embodiment, there is a circuit that comprises at least one semiconductor field-effect transistor and a magnetic tunnel junction coupled to the at least one semiconductor field-effect transistor. The magnetic tunnel junction has a control line that is configured to control operational characteristics of the at least one semiconductor field-effect transistor.

In a second embodiment, there is a circuit that comprises a semiconductor field-effect transistor and at least one magnetic tunnel junction coupled to the semiconductor field-effect transistor. The at least one magnetic tunnel junction has a control line that is configured to change resistance of the at least one magnetic tunnel junction. A change to the control line of the at least one magnetic tunnel junction restores the semiconductor field-effect transistor to a constant performance given degradation of the semiconductor field-effect transistor.

In a third embodiment, there is a method of modulating performance of a semiconductor field-effect transistor. The method in this embodiment comprises: coupling the semiconductor field-effect transistor to a magnetic tunnel junction having a control line that changes resistance of the magnetic tunnel junction; making a change to the control line; and controlling operational characteristics of the semiconductor field-effect transistor in accordance with the change made to the control line.

### BRIEF DESCRIPTION OF THE DRAWINGS

FIG. 1 is a front perspective view of a magnetic tunnel junction (MTJ);

FIGS. 2A-2B are circuit diagrams showing examples of an MTJ paired with a FET according to one embodiment of the disclosure;

FIG. 3 is a circuit diagram showing an example of an MTJ paired with a FET according to a second embodiment of the disclosure;

FIG. 4 is a circuit diagram showing an example of an MTJ paired with a FET according to a third embodiment of the disclosure;

FIG. 5 is a graphical representation of voltage threshold to drive current for a FET device shown in the circuit diagram of FIG. 4;

FIG. 6 is a circuit diagram showing an example of an MTJ paired with a FET according to a fourth embodiment of the disclosure; and

FIG. 7 is a circuit diagram showing an example of an MTJ paired with a circuit component according to a fifth embodiment of the disclosure.

### DETAILED DESCRIPTION

Embodiments of this disclosure are directed to pairing an MTJ with a FET device in order to facilitate changes to the device or to negate aging effects associated with degradation of the FET device and/or change the performance of the device for a predetermined time period or function. Changes made to the FET device are accomplished in a manner that is independent of the normal function of the device and are reversible in order to obtain extra performance for a given function and then reduced to return to the original functions if so desired. In the embodiments of this disclosure, negating degradation and/or changing performance of the FET device is obtained by making a change to the control line of the MTJ. Making a change to the control line causes a change in the resistance of the MTJ as opposed to the FET device. Consequently, changing the resistance of the MTJ allows one to indirectly control operational characteristics of the FET device and to do so without requiring the MTJ control signal to go through the FET/circuit signal path. In particular, a change to the control line of the MTJ can be used to restore the FET device to piece-wise constant or discretized constant performance in order to negate the effects of degradation. In these cases, multiple MTJ's in series and/or parallel circuits would be used with the FET in question as well as the control circuitry for the multiple MTJs. In particular, the MTJ circuit can be comprised of a single MTJ or a group of MTJs which are connected in parallel with one another, and referred to as an MTJ element. The MTJ element can then be connected to fixed resistors which are connected in series and/or parallel with one another, and referred to as an MTJ element. The choice of the numbers of MTJs, their resistance values, the resistance values of the fixed resistors, and the manner of the connections are such that the range of resistance changes which are required to tune the FET performance throughout it's life-time. In addition, a change to the control line of the MTJ can be used to produce an increase or decrease in performance in the FET device. Other operational characteristics that a change to the control line of the MTJ can compensate for include shifts in threshold voltage of the FET device or shifts in drive current provided to the FET. Other embodiments of this disclosure include pairing an MTJ to a circuit component to attain similar features as described above and to cover time zero process variations or shifts in time in FET performance as well.

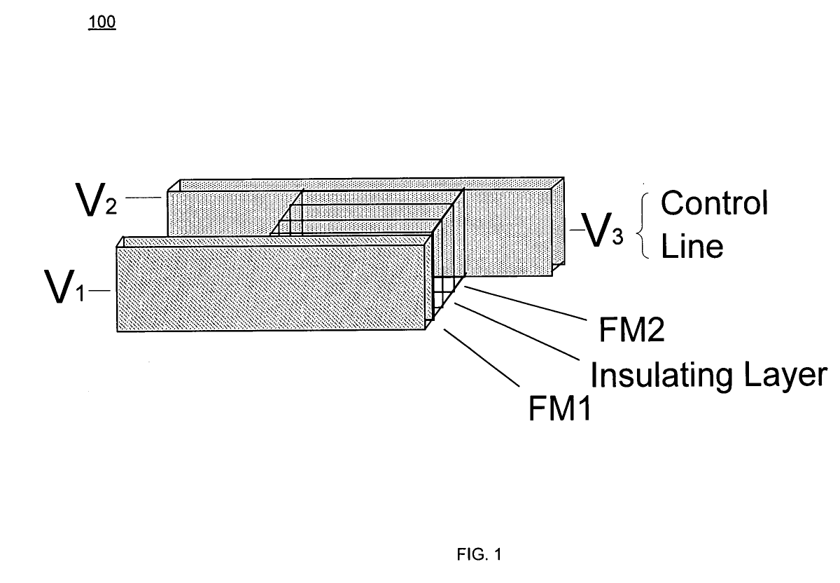

FIG. 1 is a front perspective view of a magnetic triple junction (MTJ) 100. As shown in FIG. 1, the MTJ 100 is a three terminal device that includes voltage lines V₁, V₂ and V₃. In one embodiment, voltage lines V₁ and V₂ are resistor inputs and voltage lines V2 and V₃ are the control lines that is used to cause a change in the resistance of the MTJ 100. The MT 100 further includes ferromagnets FM1 and FM2 separated by an insulating layer. The ferromagnet FM1 is designed to have a fixed magnetization while ferromagnet FM2 is designed to be flipped with a current pulse through the control line V₃ to V₂. In actual practice, the MTJ has more components which are not shown in FIG. 1, but which are well known to those skilled in the art. Specifically, FM1 is fixed in the desired orientation by abutting it to an antiferromagnet (AFM). While a natural AFM such as PtMn or IrMn or IrMnCr alone could work, for production devices, the synthetic AFM (SAFM) is used to fix the magnetization of FM1. For the purpose of this disclosure, it is not necessary to describe all of the explicit details of the complete metal structure of an MTJ.

Table 1 shows a schematic of the magnetization of ferromagnet FM1 and the orientation of ferromagnet FM2 after a positive or a negative switching current is applied to the control line V₃.

TABLE 1

| Alignment | Iₛ | M_{FM2} | M_{FM1} | R_{MTJ} |
|---|---|---|---|---|
| AP | ← | ↑ | ↓ | High |
| P | → | ↓ | ↓ | Low |

In particular, Table 1 shows vector diagrams of current through a sensor (Iₛ), the magnetization orientation of ferromagnets FM1 (M_{FM1}) and FM2 (M_{FM2}). In this table, a current pulse of V₃>V₂ will result in M_{FM2} being anti-parallel (AP) with M_{FM1} and the resistance of the MTJ being high. A current pulse of V₃<V₂ will result in M_{FM2} being parallel (P) with M_{FM1} and the resistance of the MTJ being low.

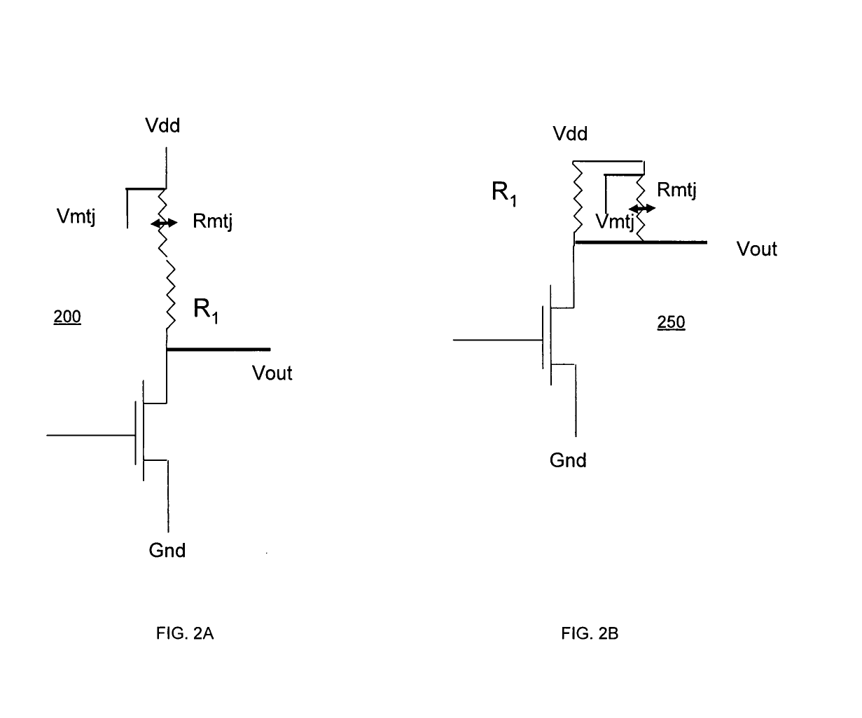

FIGS. 2A-2B are circuit diagrams showing examples of an MTJ paired with a FET according to one embodiment of the disclosure. In the circuit 200 of FIG. 2A, an MTJ which is represented by Rmtj, is in series with a resistor R₁, which is connected to the drain of an n-type FET. In this example, Rmtj is controlled by control line Vmtj. Normally, Vmtj is set at Vdd, so to change the state of the Rmtj, Vmtj has to be changed to ground. More specifically, flipping the resistance by providing a lower voltage results in a change to the state of the Rmtj.

In the circuit 200, if the voltage input to the FET is high, then the FET is on and its voltage output Vout is low because the transistor source is tied to ground. On the other hand, if the voltage input to the FET is low, then the FET is off and its voltage output Vout is high or set to Vdd because the transistor is open. Depending on the current, there is a voltage drop across the Rmtj and the resistor R₁.

Considering this configuration in a digital application, changes can be made to the Rmtj through the Vmtj to account for degradation of the FET or to increase/decrease performance of the transistor to perform a given function for a predetermined amount of time. Because changes are being made through the Rmtj (between terminals Vmtj and Vdd) and not the FET, there is no need to run another path through the FET or use a variable resistor to facilitate such changes in the FET.

The results of circuit diagram 200 would be different in an analog application because in addition to the binary on/off states of the digital device, there is the intermediate case where the voltage output Vout tracks the input voltage. Especially in this case where a tight Vout analog value is expected, a series/parallel network would be expected to be used to compensate for the FET changing. Regardless, the overall resistance of the circuit in FIG. 2A can be changed by changing the Rmtj via the Vmtj in order to account for degradation of the FET or to increase/decrease performance thereof.

In the circuit diagram 250 of FIG. 2B, the Rmtj is in parallel with the resistor R₁, which is connected to the drain of the FET. If the voltage input to the FET is high, then the FET is on and its voltage output Vout is low because the transistor source is tied to ground. On the other hand, if the voltage input to the FET is low, then the FET is off and the voltage output Vout is high or set to Vdd with a voltage drop because the transistor is open. Again, changes can be made to the FET through the Vmtj to account for degradation or to obtain increased or decreased performance. Note that one might choose to decrease performance to cause the device/circuit to last longer.

Those skilled in the art will recognize that the circuit diagrams shown in FIGS. 2A-2B are only illustrative of possible examples and that other designs are possible. For example, the Rmtj could be a parallel/series network of resistors that give additional discrete control of the voltage output Vout instead of just having single discrete control. Furthermore, the Rmtj could be used in any transistor biasing scheme for n-type or p-type FETs once the appropriate biasing was determined for the Rmtj and/or Rmtj plus fixed resistances. In these additional cases it might be beneficial to consider parallel/series Rmtj networks to add flexibility to the control. That is, with the Rmtj networks, one can change the Rmtj control values for as many times as there are Rmtj resistors. In some circuits, one change might be adequate, while in other circuits, several might be preferable.

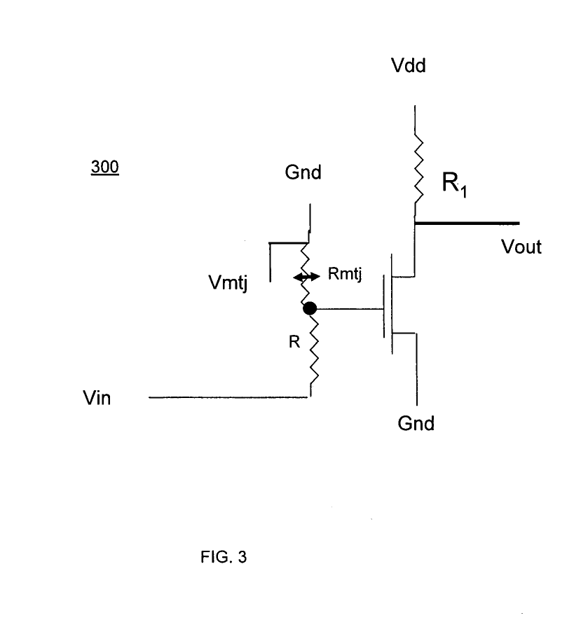

FIG. 3 is a circuit diagram 300 showing an example of an MTJ paired with a FET according to a second embodiment of the disclosure. In FIG. 3, the circuit 300 is a potential bias configuration where the Rmtj is used to control the voltage input of the FET and hence the output Vout. In this configuration, a voltage divider formed from an Rmtj and a fixed resistor R attach to the gate of the FET. A resistor R₁ couples the voltage Vdd to the drain of the FET.

In circuit 300, if the input voltage Vin is high then the FET is on and the output voltage Vout is low because the transistor source is tied to ground. On the other hand, if Vin is low, then the FET is off and the voltage output Vout is set to a high voltage with a voltage drop across the resistor R₁. If Vin was lower than actually desired, then one might want to change the value of the voltage divider network (i.e., Rmtj and R). For example, increasing the value of Rmtj by making a change to Vmtj might provide more voltage at the gate of the FET. As is apparent to those skilled in the art, circuit 300 is more suitable for analog applications rather than digital applications because tighter controls are generally not needed to perform the on-off functions of digital applications, whereas analog applications have a greater need for tighter controls of the output so that changes do not occur so easily.

Regardless of whether circuit 300 is used for digital or analog applications, changes to the FET are implemented by making changes to the state of the Rmtj through the Vmtj. Because Vmtj is normally at ground for the case shown, the state of the Rmtj is changed by changing Vmtj to Vdd. As a result, modulation of the circuit 300 can be made to account for degradation and/or to obtain increased or decreased performance without going directly through the FET to make the change.

Those skilled in the art will recognize that circuit 300 shown in FIG. 3 is only illustrative of one possible example and that other designs are possible. For example, the Rmtj in FIG. 3 could be a parallel/series network of resistors that gives additional discrete control of the output instead of just a single discrete control.

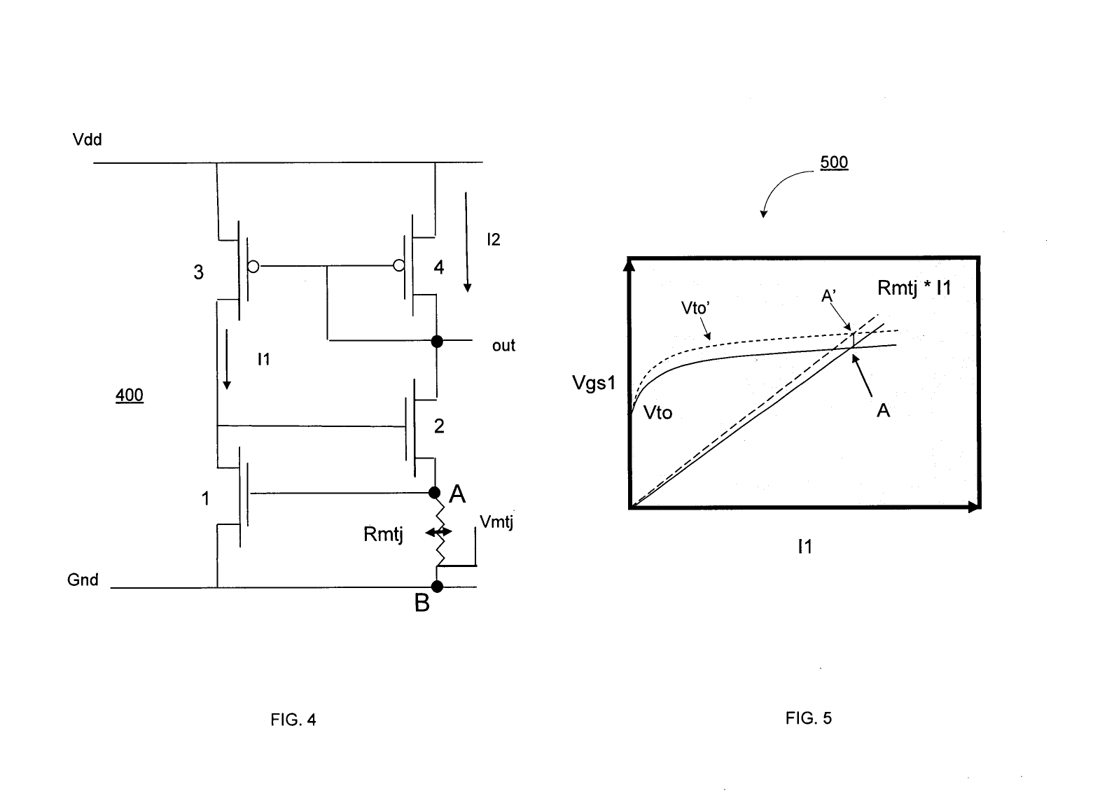

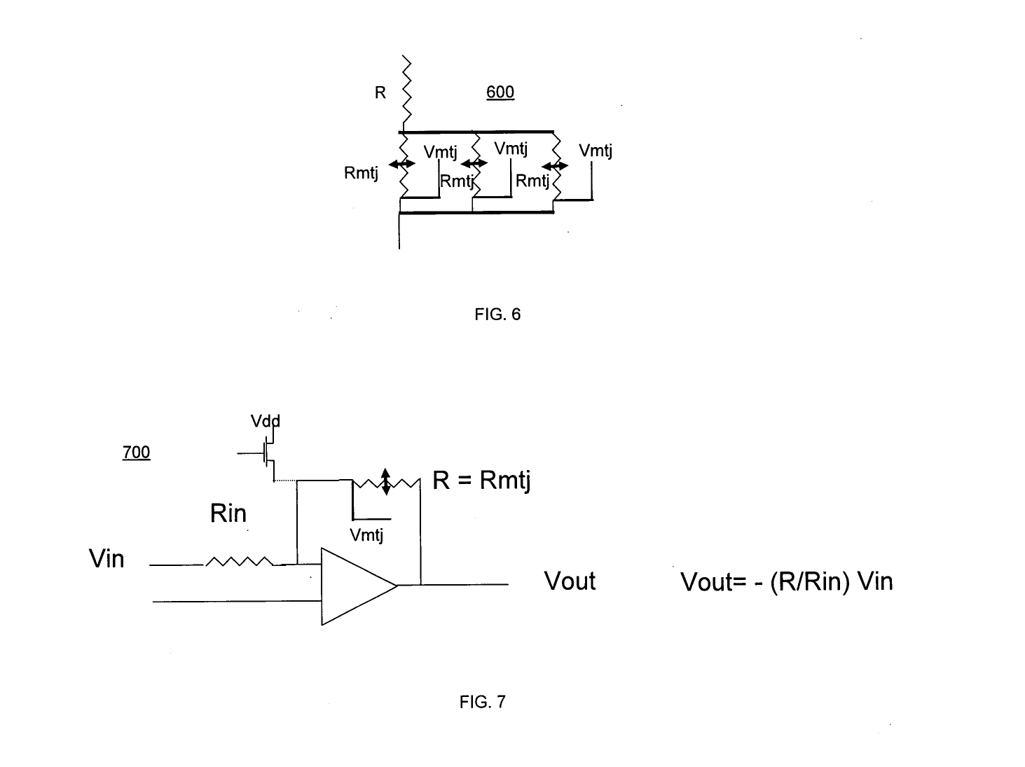

FIG. 4 is a circuit 400 showing an example of an MTJ paired with a FET according to a third embodiment of the disclosure. In particular, the circuit 400 shows a reference circuit with explicit biasing. As shown in FIG. 4, the circuit 400 includes four FETs; FET 1, FET 2, FET 3 and FET 4. FETs 1 and 2 are of the n-type, whereas FETS 3 and 4 are of the p-type. The drain of FET 1 is connected to the gate of FET 2 and the gates of FETS 3 and 4 are connected to each other. An Rmtj is used to change the performance of the circuit 400 via a change to FET 1 by taking Vmtj from ground to Vdd. A more detailed description of this circuit but without the use of the Rmtj is provided in REF Analog Design for CMOS VLSI Systems, Franco Maloberti, page 180 (Kluwer Academic Publishers, Boston, 2001). The combination of four FETs are used to generate currents I1 and I2. In particular, FETs 3 and 4 develop ratioed currents (i.e., I1 and I2) with respect to each other in the two branches of the circuit 400 and is explained as follows: if (W3/L3)=(W4/L4), then I2=I1, and Vgs1=Rmtj*I1, wherein (W2/L2), W3/L3 and W4/L4 are non-critical in the calculation but could be expected to be all greater than (W1/L1) and Vgs is the voltage between the gate and source of FET 1. As a result, Vgs1=Vth1+(2*I1/(u*Cox1)*(W1/L1))̂0.5 for Vgs1>Vth1, where Vth1 is the threshold voltage of FET 1. Using the above equations, one can generate a numerical example that describes the operation of circuit 400. For example, if I2=2 ma, (W1/L1)=50, Vth=0.6V, (u*Cox1)=120 uA/V̂2, then Vgs1=1.416 V and Rmtj=708 ohms. If Vth1 were increased by 50 mV, then Vgs1=1.466 V and Rmtj would need to be increased to 733 ohms to return Vgs1 to its original value for a constant current I1=I2=2 ma. A single change in operating point could be accomplished with a single MTJ; that is by making a change to Rmtj via the Vmtj. If several changes were anticipated, an MTJ series and/or parallel network of MTJs could be used to facilitate this change. For this example, it is estimated that a change of only about 3.5% is necessary to offset the Vth increase. Note that MTJs are generally capable of bringing about 2× changes in resistance depending on the MTJ films and film thicknesses. Also, note that depending on the resistance change desired, one could use a combination of series and/or parallel resistors which are both MTJ resistors and fixed resistors to achieve the desired resistance and resistance change. For example, a voltage divider circuit 600 like the one shown in FIG. 6 could be used. In the voltage divider circuit of FIG. 6, the voltage divider circuit 600 includes three Rmtj resistors in parallel that are themselves in series with a fixed resistor R. FIG. 5 shows a graphical representation of what happens in circuit 400 when the Rmtj is varied by taking Vmtj from ground to Vdd. In particular, FIG. 5 shows that to keep node A within circuit 400 constant, the resistance of Rmtj has to be changed to a value that allows Vgs1 to give a constant current output. This change to the Rmtj will impact the turn-on voltage applied at Vgs1 as shown by the Vto′ representation, thereby changing Vgs1 accordingly to facilitate the necessary change.

FIG. 7 is a circuit 700 showing an example of an MTJ paired with a circuit component according to a fifth embodiment of the disclosure. In FIG. 7, an operational amplifier is the circuit component that is controlled by the Rmtj. In circuit 700, a FET is coupled to the Rmtj and one input terminal of the operational amplifier. The FET is used in this configuration because the terminal for Vmtj cannot be directly and conveniently connected externally to circuit 700 due to the input resistor Rin. If the output voltage Vout from the operational amplifier changes or if it is desired to bring about a certain change in performance, then one can change the Rmtj to control the gain of the operational amplifier to be a discretized or step-wise constant during the life of the component.

Those skilled in the art will recognize that circuit 700 shown in FIG. 7 is only illustrative of one possible example and that other designs are possible. For example, the state of the Rmtj could be controlled through the combination of Vmtj and the input voltage Vin. Alternatively, a pass gate device could be inserted between the input resistor Rin and Vmtj.

FIGS. 2-7 show only a few examples of how an MTJ could be paired to a FET or a circuit component in order to facilitate performance changes to the FET or circuit component to account for eventual degradation or instances where extra performance is needed to perform a given function for a certain time before reverting back to its normal performance. In all of the cases shown in the examples of FIGS. 2-7, the MTJ provides an “external” means of modulating the FET or circuit component without having to go through the FET or component themselves.

It is apparent that there has been provided with this disclosure an approach for pairing a magnetic tunnel junction to a semiconductor field-effect transistor. While the disclosure has been particularly shown and described in conjunction with a preferred embodiment thereof, it will be appreciated that variations and modifications will occur to those skilled in the art. Therefore, it is to be understood that the appended claims are intended to cover all such modifications and changes as fall within the true spirit of the invention.

What is claimed is:

1. A circuit, comprising:
at least one semiconductor field-effect transistor; and
a magnetic tunnel junction, coupled to the at least one semiconductor field-effect transistor, the magnetic tunnel junction having a control line that is configured to control operational characteristics of the at least one semiconductor field-effect transistor.

2. The circuit according to claim 1, wherein the control line controls operational characteristics of the at least one semiconductor field-effect transistor by changing resistance of the magnetic tunnel junction.

3. The circuit according to claim 2, wherein the changing of resistance of the magnetic tunnel junction compensates for shifts in threshold voltage of the at least one semiconductor field-effect transistor or shifts in drive current provided to the at least one semiconductor field-effect transistor.

4. The circuit according to claim 3, wherein the compensation provided by the changing of resistance of the magnetic tunnel junction is piece-wise constant or discretized constant.

5. The circuit according to claim 2, wherein the changing of resistance of the magnetic tunnel junction compensates for variation in the FET performance either due to time zero process variations or to shifts through time.

6. The circuit according to claim 2, wherein the changing of resistance of the magnetic tunnel junction produces an increase or decrease in performance in the at least one semiconductor field-effect transistor.

7. The circuit according to claim 1, wherein the control line runs through a control layer of the magnetic tunnel junction without passing through the at least one semiconductor field-effect transistor.

8. The circuit according to claim 1, further comprising a resistor network coupled to the at least one semiconductor field-effect transistor and the magnetic tunnel junction.

9. A circuit, comprising:
a semiconductor field-effect transistor; and
at least one magnetic tunnel junction, coupled to the semiconductor field-effect transistor, the at least one magnetic tunnel junction having a control line that is configured to change resistance of the at least one magnetic tunnel junction; wherein a change to the control line of the at least one magnetic tunnel junction restores the semiconductor field-effect transistor to a constant performance given degradation of the semiconductor field-effect transistor.

10. The circuit according to claim 9, wherein the restored constant performance is piece-wise constant or discretized constant.

11. The circuit according to claim 9, wherein the change to the control line of the at least one magnetic tunnel junction produces an increase or decrease in performance in the semiconductor field-effect transistor.

12. The circuit according to claim 9, wherein the control line runs through a control layer of the at least one magnetic tunnel junction without passing through the semiconductor field-effect transistor.

13. The circuit according to claim 9, wherein the change to the control line of the at least one magnetic tunnel junction provides compensation for variation in the FET performance due to shifts through time.

14. The circuit according to claim 9, further comprising a resistor network coupled to the semiconductor field-effect transistor and the at least one magnetic tunnel junction.

15. The circuit according to claim 14, wherein the change to the control line of the at least one magnetic tunnel junction modulates output from the resistor network.

16. The circuit according to claim 9, further comprising a circuit component coupled to the at least one magnetic tunnel junction, wherein the change to the control line of the at least one magnetic tunnel junction provides control of performance characteristics of the circuit component.

17. A method of modulating performance of a semiconductor field-effect transistor, comprising:
coupling the semiconductor field-effect transistor to a magnetic tunnel junction having a control line that changes resistance of the magnetic tunnel junction;
making a change to the control line; and
controlling operational characteristics of semiconductor field-effect transistor in accordance with the change made to the control line.
